(19) United States
(12) Patent Application Publication
(10) Pub. No.: US 2006/0249303 A1
(43) Pub. Date: Nov. 9, 2006

(54) Connectorless electronic interface between rigid and compliant members using hemi-ellipsoidal surface features

(76) Inventors: Kenneth W. Johnson, Colorado Springs, CO (US); Brock J. LaMeres, Colorado Springs, CO (US)

Correspondence Address: AGILENT TECHNOLOGIES INC., INTELLECTUAL PROPERTY ADMINISTRATION, M/S DU404, P.O. BOX 7599, LOVELAND, CO, 80537-0599, US

(21) Appl. No.: 11/121,561

(22) Filed: May 4, 2005

(51) Int. Cl. H05K 1/11; H05K 1/14

(52) U.S. Cl. 174/261; 361/803; 361/784

(57) ABSTRACT

A connectorless board-to-board, cable-to-board or cable-to-cable interconnect is presented. The interconnect is fashioned from solder beads or hemi-ellipsoidal surface structures on traces of a printed circuit board on one portion of the interconnect and contact pads on traces of a flexible interconnect media of a second portion of the interconnect or vice versa.

### BACKGROUND

With the operating speed of many electronic devices entering the gigahertz range, smaller physical distances and geometries in electronic product design have become necessary to limit deleterious transmission line effects, such as electronic signal reflections and oscillations. One of several design areas affected by these advances in operating speed is interconnection methodology. In response to these advances, electronic connectors utilized on printed circuit boards (PCBs) have had to become smaller while simultaneously containing more signal conductors or pins. For example, the electrical connection of two printed circuit boards in an electronic system, normally accomplished by way of wire cables and connectors, or by way of standard board-edge connectors, often results in relatively long transmission lines between the two boards, allowing unwanted signal reflections to exist. To mitigate these effects, shorter transmission lines between electronic components in an electronic system are advantageous.

To that end, direct connection between two PCBs in the absence of a standard connector is desirable, as the transmission line lengths for such a connection scheme are reduced to a minimum. The most direct connection between two PCBs involves soldering the edge of one PCB to the side of the second PCB. Unfortunately, such a configuration does not readily facilitate replacement or repair and may not be mechanically stable, making the process of soldering difficult.

Many board-to-board, cable-to-cable or cable-to-board connections are made using a typical, off the shelf connection. These are generally reliable and effective interfaces. However, in some instances, it is preferable to create a custom connection. The reasons for this are varied, but usually include space limitations for the connection, a need to obtain a certain physical ground-to-signal distance (e.g., impedance control, shielding, crosstalk, etc.), or a need to make a connection to mating signals in a custom spacing. In such applications, the cost, reliability, development or availability of materials makes the creation of a custom connector very difficult to undertake or compromises the end result by not supplying all of the needed features for the cost constraints.

The inventors of the present invention have determined a need for customized board-to-board, cable-to-board and cable-to-cable connections inexpensively and reliably.

### BRIEF DESCRIPTION OF THE DRAWINGS

An understanding of the present teachings can be gained from the following detailed description, taken in conjunction with the accompanying drawings of which:

FIG. 1 illustrates an orthogonal view of two sides of a connectorless electronic interface prior to mating.

FIG. 2 illustrates a side, cut-away view of the two sides of a connectorless electronic interface of FIG. 1 in a mated position.

FIG. 3A is a top view of a portion of a printed circuit board showing the x- and y-dimensions in the x-, y-, z-coordinate system of a trace with a hemi-ellipsoidal surface feature.

FIG. 3B is a cross-sectional side view showing the x- and z-dimensions in the x-, y-, z-coordinate system of the portion of the printed circuit board and trace of FIG. 3A.

FIG. 3C is a cross-sectional side view of the portion of the printed circuit board and trace of FIGS. 3A and 3B showing the y- and z-dimensions in the x-, y-, z-coordinate system.

FIG. 4 is a flowchart illustrating a method of manufacture of a hemi-ellipsoidal surface feature on a trace of a printed circuit board.

FIG. 5A is a top view of a portion of a printed circuit board showing the x- and y-dimensions in the x-, y-, z-coordinate system of a pair of traces with hemi-ellipsoidal surface features implemented according to the method of FIG. 4.

FIG. 5B is a cross-sectional side view showing the x- and z-dimensions in the x-, y-, z-coordinate system of the portion of the printed circuit board and trace of FIG. 5A after application of the solder mask but prior to application of solder paste.

FIG. 5C is a cross-sectional side view showing the y- and z-dimensions in the x-, y-, z-coordinate system of the portion of the printed circuit board and trace of FIGS. 5A and 5B after application of the solder mask but prior to application of solder paste.

FIG. 5D is a cross-sectional side view showing the x- and z-dimensions in the x-, y-, z-coordinate system of the portion of the printed circuit board and trace of FIGS. 5A-5C after application of solder paste.

FIG. 5E is a cross-sectional side view showing the y- and z-dimensions in the x-, y-, z-coordinate system of the portion of the printed circuit board and trace of FIGS. 5A-5D after application of solder paste.

FIG. 5F is a cross-sectional side view showing the x- and z-dimensions in the x-, y-, z-coordinate system of the portion of the printed circuit board and trace of FIGS. 5A-5E after soldering.

FIG. 5G is a cross-sectional side view showing the y- and z-dimensions in the x-, y-, z-coordinate system of the portion of the printed circuit board and trace of FIGS. 5A-5F after soldering.

### DETAILED DESCRIPTION

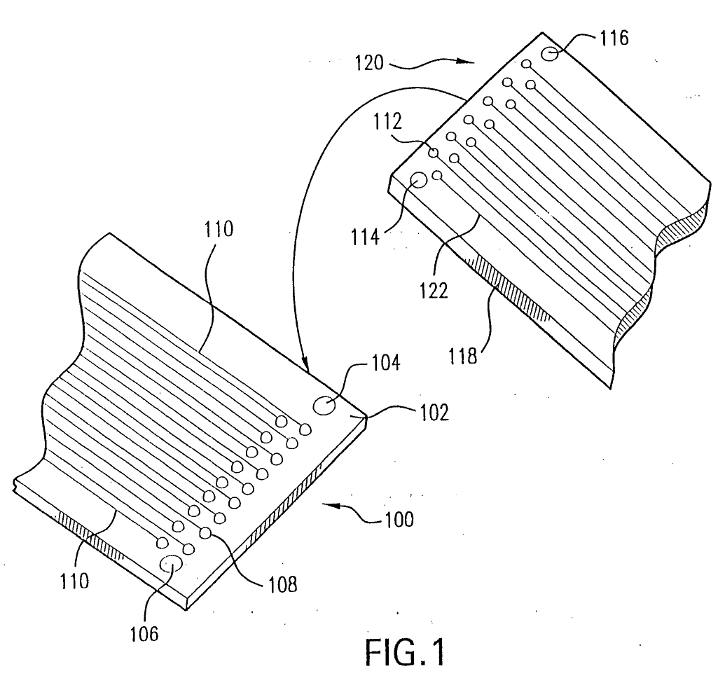

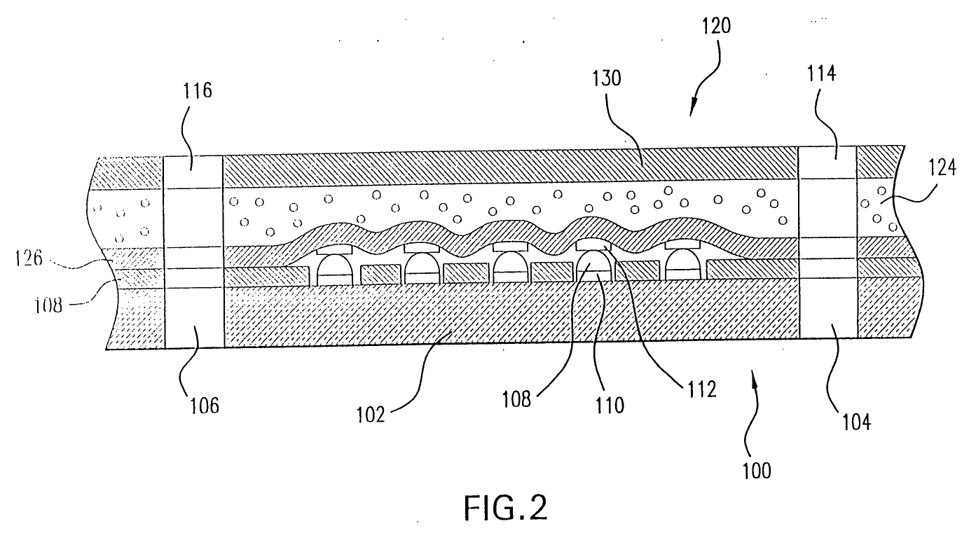

FIG. 1 is an orthogonal view of two components 100 and 120 of an unmated, connectorless electronic interface. FIG. 2 illustrates a side, cut-away view of the interface of FIG. 1 in a connected position. Specifically, interface part 100 may include a printed circuit board 102 with numerous traces 110, hemi-ellipsoidal surface features or solder beads 108 arranged along the traces 110, solder mask 128 and alignment features 104 and 106. Interface part 120 may include numerous traces 122 with contact pads 112 formed on flex 126 over foam 124 with a stiffener 130 and alignment features 114 and 116. As will be readily appreciated, when the two parts of the interface are mated, alignment features 104 and 106 are aligned with alignment features 114 and 116 and the two sides 100 and 120 of the interface are brought into compressive contact, deforming the flex 126 and foam 124 layers of interface part 120. As the two sides 100 and 120 of the interface are brought into compressive contact, the surface of the solder beads 108 are purged of any surface contamination by a slight deformation of the bead. The deformation causes microscopic ruptures in the beads surface exposing the uncontaminated solder of the beads interior. This uncontaminated material tends to extrude through the cracks of the ruptured surface presenting a clean surface so that a good electrical connection can be made between the beads 108 and the pads 112 as the flex 126 and foam 124 are deformed. The amount of deformation the bead is subjected to is controlled by the foam 124.

The interface of FIGS. 1 and 2 may be used as interconnect for board-to-board, cable-to-board or cable-to-cable. Throughout this document, hemi-ellipsoidal surface feature and solder bead are used interchangeably.

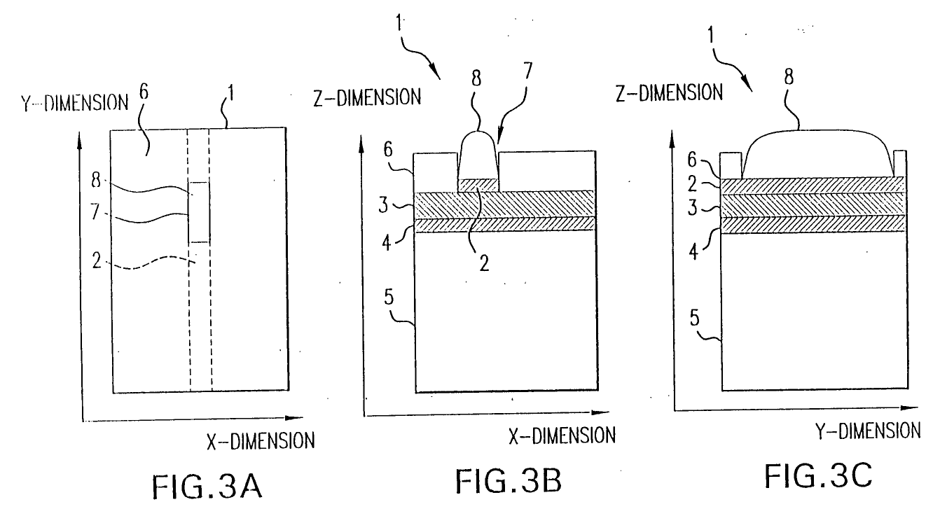

An exemplary first interface part 100 may include a printed circuit board as shown in FIGS. 3A-3C. As shown in FIGS. 3A-3C, a printed circuit board 1 includes a substrate 5, a ground plane 4, and at least one dielectric layer 3 with a trace 2 printed, deposited, or otherwise attached thereon. A solder mask 6 with a hole 7 formed over the trace 2 at a location where a solder bead 8 is positioned is layered over the exposed surfaces of the dielectric layer 3 and trace layer 2. A solder bead 8 is conductively attached to the trace 2 within the solder mask hole 7. The solder bead 8 projects above the exposed surrounding surfaces of the solder mask 6 to form an exposed localized high point on the trace 2 that may be used to make contact with a contact pad of an opposing interconnect part. In one embodiment, the solder bead 8 is a solder bead with a length (in the y-dimension) larger than the width (in the x-dimension) of the trace to provide maximum contact surface.

In one exemplary method of manufacture of solder beads 8, 18, 108 on traces 3, 12, 110 the invention may utilize existing printed circuit board fabrication processes, thereby keeping costs low. As known in the art, virtually every printed circuit board is constructed with high-speed signals appearing on the outer layers due to the ability to more easily control impedances on the outer layers. The two outer layers are also typically coated with a solder mask that is used to assure that only exposed copper (or other conductive materials) areas will retain solder paste that is applied via a screen printing process. Holes in the solder mask assure that only those areas of copper that should be soldered will receive solder paste.

The second interface part 120 may be formed as a flex circuit or any available pliable, flexible interconnect media. Furthermore, the interface 120, may be a combination of flex circuit and other typical media such as ribbon cable, coaxial cable, discrete wires, printed circuit boards or other known interconnect media that are electrically terminated, such as soldered, to the primary flexible interface. The constraint being that the assembly be compliant in the area of the foam 124 and pads 122. A flex circuit may be manufactured in the same manner as printed circuit board with the dielectric layer of the flex circuit made of a flexible material, such as a high temperature, high strength plastic like polyimide, rather than the more typical rigid dielectric materials (e.g., fiberglass) used in traditional printed circuit boards. Ribbon cables, coaxial cables, discrete wires and the like may be manufactured of any known means.

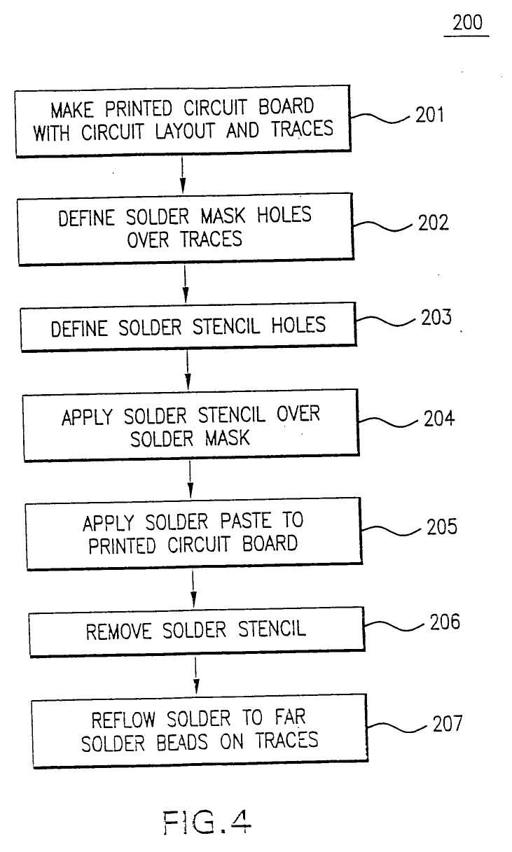

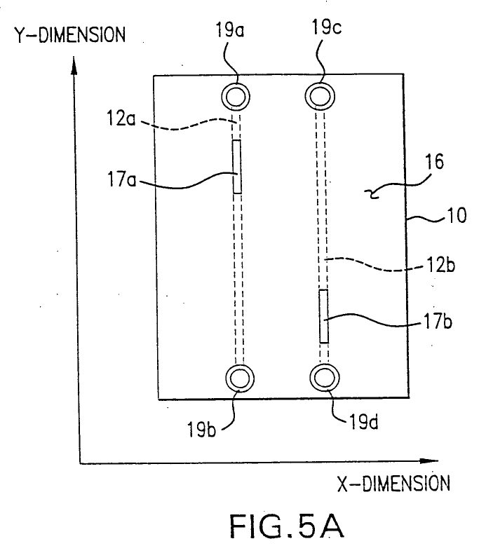

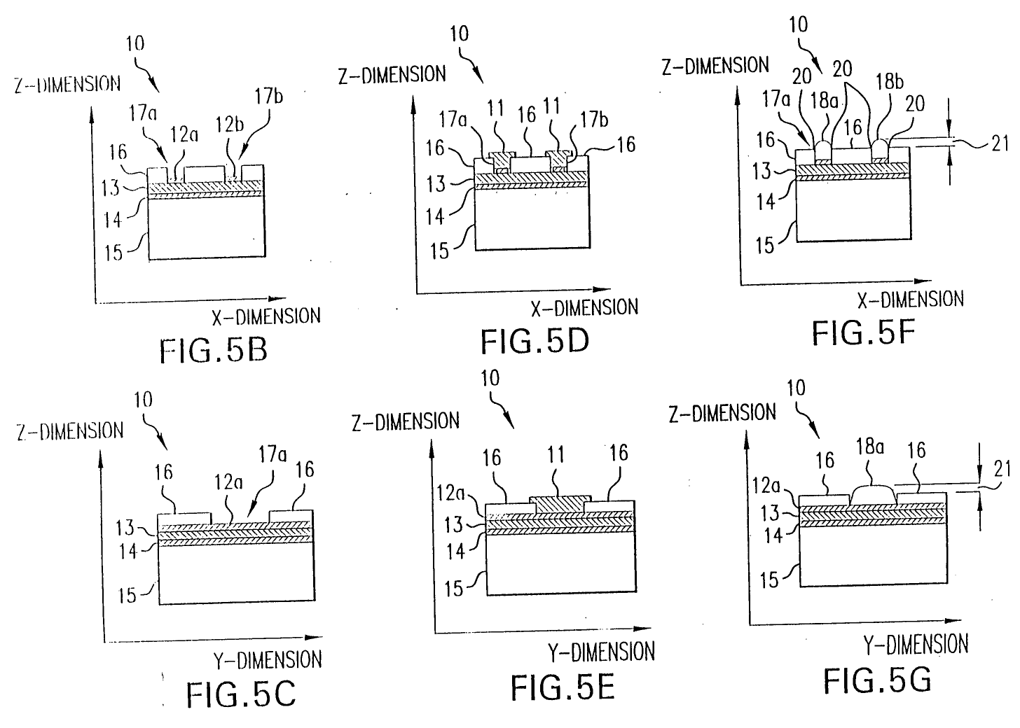

FIG. 4 is an operational flowchart illustrating a preferred method 200 of manufacture of a solder bead on a trace of a printed circuit board, and FIGS. 5A-5G include various views of a portion of a printed circuit board 10 during manufacture of solder beads 18a, 18b in accordance with the method of FIG. 4. Referring now to FIG. 4 with additional reference to FIGS. 5A-5G, in the preferred method of manufacture of solder beads of the invention, the printed circuit board 10 is fabricated in step 201 to the point of printing, depositing, or otherwise layering the traces 12a, 12b on which solder beads 18a, 18b are to be implemented. In step 202, solder mask holes 17a, 17b (in addition to holes 19a, 19b, 19c, 19d for the traditional points of solder—e.g., component pin-to-trace solder points) are defined and implemented in the printed circuit board solder mask 16 in locations over traces 12a, 12b at desired solder bead locations, as illustrated in FIGS. 5A, 5B, and 5C.

The positions of solder mask holes 17a, 17b in the solder mask 16 are governed by rules on minimum spacing and proximity to other devices that must be avoided. In step 203, holes are defined in a solder stencil (shown in FIG. 8B) and in step 204 the solder stencil is applied over the mask 16 (shown in FIG. 8C), such that the holes in the solder stencil are aligned over solder mask holes 17a, 17b in the solder mask 16 along a diagonal in the solder stencil.

Once solder mask holes 17a, 17b are located and the solder mask 16 is produced, printed circuit board fabrication proceeds as is normal in the art. To this end, in step 205, solder paste 11 is applied to the board 10, thereby filling the solder mask holes 17a, 17b, using the standard well-known silk-screen process, as illustrated in hole 17a in FIGS. 5D and 5E. The area of the hole and the thickness of the solder stencil determines the volume of solder paste 11 that ends up in the hole 17a. It should be noted that the solder mask hole 17a, 17b may not be completely filled when the solder paste is deposited, but any voids are filled during the reflow step. In step 206, the solder stencil is removed leaving bricks or islands 11 of solder paste, as shown in FIGS. 5D and 5E.

In step 207, the solder paste is soldered to the conductive areas exposed by the solder mask, for example using a reflow soldering technique. Soldering is a very well understood process. As known in the art, the solder paste may be approximately 50% metal and 50% flux by volume. When the solder paste melts during reflow soldering, the flux burns off, preventing oxidation of the solder and reducing the end volume. Surface tension causes the paste to reform from a rectilinear shape, as defined by the mask hole, into a semi-ellipsoidal shape defined by the exposed copper. Thus, the melted solder will retract from the walls 20 of solder mask hole 17a in the solder mask 16 and form a solder bead 18, as illustrated in FIGS. 5F and 5G that can project some distance 21 above the solder mask 16. This distance, or solder bead thickness 21 in the z-dimension of the x-, y-, z-coordinate system, is determined by the area of the exposed trace 12a, 12b and the original volume of the solder paste 11.

When the solder is reflowed, it will spread out on the trace 12 due to its affinity for copper or other conductive material and it will exit the solder mask 16 due to its lack of affinity for the mask material. Thus, the molten solder will bead up on the exposed copper or other conductive trace material 12.

The dimensions of the solder mask and stencil mask holes can be used to calculate the solder bead height and length. The height of the resulting solder bead may be determined by the area of the solder mask hole 17 and the volume of the solder paste applied to the board or the pre-reflow solder paste. The area of the hole 17 in the solder mask 16 is: Area=W*L+π*(W/2)². The pre-reflow solder paste volume is the area of the solder stencil hole multiplied by the stencil thickness T. That is the pre-reflow solder paste volume=T*D². Since solder paste, by volume, is approximately 50% flux, about 50% of the paste volume will be left as a solder bead 18 after the reflow process step. That is, the post-reflow solder bead 18 volume=T*D²/2. The height H of the bead 18 may be such that the resultant bead 18, standing on the underlying signal trace 12, will protrude above the solder mask 16 by 2 to 3 thousandths of an inch. The height H of bead 28 is approximately the post-reflow solder volume divided by the solder mask opening area or:
H=(T*D²/2)/(W*L+π*(W/2)²)

Given stencil thickness T, stencil hole diameter D, solder mask opening width W, and bead height H, than bead length L is approximately:
L=((T*D²/2)/(H*W))−π*W/4

Although one embodiment of the present invention has been shown and described, it will be appreciated by those skilled in the art that changes may be made in these embodiments without departing from the principles and spirit of the invention, the scope of which is defined in the claims and their equivalents. For example, the alignment features 104, 106, 114 and 116 are shown as holes, but may be any known alignment feature. For example, the solder bumps may be formed on the flexible interconnect media and the pads on the other side of the interface with the result being no connector, just solder bump to contact pad interface. Basically, one half of the interconnect is rigid and the other half is compliant. Either half may contain the solder bead or the contact pad. The result being that the flexible portion of the interconnect compensates for the non-uniformly flat part of the rigid portion and the foam controls the amount of force applied to the solder bead.

What is claimed is:

1. An electrical interface comprising:
a first side of the electrical interface having hemi-ellipsoidal surface features on traces;
a second side of the electrical interface having contact pads on traces; wherein when the first side of the electrical interface is mated with the second side of the electrical interface, the contact pads are brought into compressive contact with the contact pads.

2. The electrical interface according to claim 1, wherein the hemi-ellipsoidal surface features comprise solder beads.

3. The electrical interface according to claim 1, wherein the first side of the electrical interface comprises a printed circuit board and the second side of the electrical interface comprises a flexible interconnect media.

4. The electrical interface according to claim 3 further comprising alignment features on the printed circuit board and the flexible interconnect media to aid in mating the printed circuit board to the flexible interconnect media.

5. The electrical interface according to claim 3, wherein the flexible interconnect media is a ribbon cable.

6. The electrical interface according to claim 3, wherein the flexible interconnect media is a coaxial cable.

7. The electrical interface according to claim 3, wherein the flexible interconnect media comprises discrete wires.

8. The electrical interface according to claim 3, wherein the flexible interconnect media comprises a flex circuit.

9. The electrical interface according to claim 1, wherein the electrical interface comprises a cable-to-board interface.

10. The electrical interface according to claim 1, wherein the electrical interface comprises a cable-to-cable interface.
